(19) United States
(12) Patent Application Publication
(10) Pub. No.: US 2024/0037382 A1
(43) Pub. Date: Feb. 1, 2024

(54) METHOD AND DEVICE FOR IMPLEMENTING AVERAGE POOLING OF NEURAL NETWORK, AND STORAGE MEDIUM

(71) Applicant: INSPUR SUZHOU INTELLIGENT TECHNOLOGY CO., LTD., Suzhou, Jiangsu (CN)

(72) Inventors: Jingjing CHEN, Suzhou, Jiangsu (CN); Ping HUANG, Suzhou, Jiangsu (CN); Ruizhen WU, Suzhou, Jiangsu (CN); Lin WANG, Suzhou, Jiangsu (CN)

(21) Appl. No.: 18/265,648

(22) PCT Filed: Dec. 30, 2021
(86) PCT No.: PCT/CN2021/142857

§ 371 Date: Jun. 6, 2023

(30) Foreign Application Priority Data
Aug. 18, 2021 (CN) 202110945903.7

(51) Int. Cl. G06N 3/067; G02B 6/42; H01L 27/146

(52) U.S. Cl. CPC G06N 3/067; G02B 6/4215; H01L 27/14643

(57) ABSTRACT

The method includes: acquiring a plurality of to-be-treated optical signals with unequal wavelengths; inputting the to-be-treated optical signals into a micro-ring-resonator array, wherein the micro-ring-resonator array includes a plurality of micro-ring resonators that are connected in series; applying a corresponding electric current to the micro-ring-resonator array, to adjust a transfer function of each of the micro-ring resonators to reach a target value; and feeding an optical signal outputted by the micro-ring-resonator array into a photodiode, to obtain an operation result of the average pooling of the neural network.

### CROSS REFERENCE TO RELEVANT APPLICATIONS

The present application claims the priority of the Chinese patent application filed on Aug. 18, 2021 before the China National Intellectual Property Administration with the application number of 202110945903.7 and the title of “METHOD AND DEVICE FOR IMPLEMENTING AVERAGE POOLING OF NEURAL NETWORK, AND STORAGE MEDIUM”, which is incorporated herein in its entirety by reference.

### FIELD

The present application relates to the technical field of photoelectric chips, and particularly relates to a method for performing average pooling of a neural network, a device and a storage medium.

### BACKGROUND

Chips are the base and core of the modern electronic information industry. With the globalization and high-speed development of technology, the data volume required to be processed is sharply increasing, and the corresponding data processing models and algorithms are also continuously increasing, the result of which is the increasingly higher requirements on the computing power and the power consumption. However, the current electronic computers of the Von Neumann architecture and the Harvard architecture have problems such as a transmission bottleneck, an increasing power consumption and a computing power bottleneck, and have become increasingly more difficult to satisfy the demands on the computing power and the power consumption in the big-data era. Therefore, it is currently a critical problem to increase the operational speed while reducing the operational power consumption.

One of the very promising approaches to solve the current problem in the computing power and the power consumption is to replace the conventional electronic calculation approach with the photon calculation approach. Photon calculation chips, by using photons as the information carrier, have the advantages of high-speed concurrency and a low power consumption, and thus is considered as the most promising solution for high-speed, high-data-volume and artificial intelligence calculation and processing in the future. Currently, the most commonly used industrial solution of Optical Neural Networks (ONN) is exclusive devices. However, that is usually suitable to solving the part of the multiplication and addition operation based on convolution operation. In Artificial Neural Networks (ANN), although the operation of the maximum volume is from the convolution operation, a large amount of operation of the average pooling of the neural networks exists.

Therefore, how to realize the simulated operation of the average pooling in neural networks is a technical problem required to be solved urgently by a person skilled in the art.

### SUMMARY

The solutions of the present application are as follows:

A method for performing average pooling of a neural network, where the method includes:
acquiring a plurality of to-be-treated optical signals with unequal wavelengths;
inputting the to-be-treated optical signals into a micro-ring-resonator array, where the micro-ring-resonator array includes a plurality of micro-ring resonators that are connected in series;
applying a corresponding electric current to the micro-ring-resonator array, to adjust a transfer function of each of the micro-ring resonators to reach a target value; and
feeding an optical signal outputted by the micro-ring-resonator array into a photodiode, to obtain an operation result of the average pooling of the neural network.

In some embodiments, each of the micro-ring resonators includes one straight waveguide and one micro-ring waveguide; and micro-ring radii of the micro-ring resonators are unequal.

In some embodiments, a quantity of types of the wavelengths of the to-be-treated optical signals is equal to a quantity of the micro-ring resonators; and
the wavelengths of the to-be-treated optical signals correspond to radii of the micro-ring resonators one to one.

In some embodiments, before the operation of applying the corresponding electric current to the micro-ring-resonator array, the method further includes:
by the to-be-treated optical signals with the unequal wavelengths, performing resonance with the corresponding micro-ring resonators.

In some embodiments, the straight waveguides of all of the micro-ring resonators of the micro-ring-resonator array are a same shared straight waveguide;
the shared straight waveguide is provided with an input port and a direct-passing port; and
the photodiode is located at the direct-passing port.

In some embodiments, light intensities of the to-be-treated optical signals with the unequal wavelengths are unequal.

In some embodiments, when the to-be-treated optical signals with four wavelengths are inputted into the micro-ring-resonator array, the target value is ¼; and
when the target value is ¼, the operation result of 2×2 average pooling of the neural network is obtained.

In some embodiments, it is determined that the to-be-treated optical signals with four wavelengths are inputted into the micro-ring-resonator array, and, based on the determination result, the target value is ¼; and it is determined that the target value is ¼, and, based on the determination result, the operation result of 2×2 average pooling of the neural network is obtained.

An embodiment of the present application further provides a computer device, and the computer device includes a memory and one or more processors, and the memory stores a computer-readable instruction, and the computer-readable instruction, when executed by the one or more processors, causes the one or more processors to implement the operations of the method for performing average pooling of a neural network according to any one of the above embodiments.

An embodiment of the present application further provides one or more non-transitory computer-readable storage mediums storing a computer-readable instruction, and the computer-readable instruction, when executed by one or more processors, causes the one or more processors to implement the operations of the method for performing average pooling of a neural network according to any one of the above embodiments.

The details of one or more embodiments of the present application are provided in the following drawings and description. The other characteristics and advantages of the present application will become apparent from the description, the drawings and the claims.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are merely embodiments of the present application, and a person skilled in the art may obtain other figures according to the provided figures without paying creative work.

FIG. 1 is a flow chart of a method for performing average pooling of a neural network according to one or more embodiments of the present application;

FIG. 2 is a schematic diagram of average pooling according to one or more embodiments of the present application;

FIG. 3 is a schematic diagram of the result of micro-ring resonators according to one or more embodiments of the present application;

FIG. 4 is a light-intensity distribution diagram of the micro-ring resonators in a disresonance situation according to one or more embodiments of the present application;

FIG. 5 is a light-intensity distribution diagram of the micro-ring resonators in a resonance situation according to one or more embodiments of the present application;

FIG. 6 is a schematic diagram of the variation of the transfer functions of the micro-ring resonators with the phases according to one or more embodiments of the present application;

FIG. 7 is a schematic structural diagram of an apparatus for performing average pooling of a neural network by using the micro-ring resonators according to one or more embodiments of the present application; and

FIG. 8 is an internal structural diagram of a computer device according to one or more embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

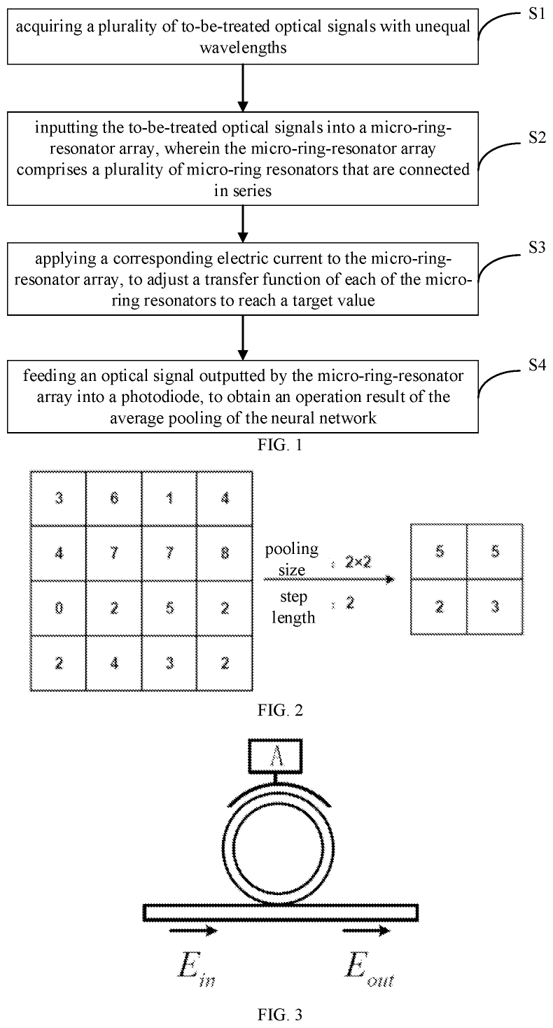

An embodiment of the present application provides a method for performing average pooling of a neural network, and the subject of the implementation of the method may be a server or a terminal. As shown in FIG. 1, the method includes the following steps:

S101: acquiring a plurality of to-be-treated optical signals with unequal wavelengths.

S102: inputting the to-be-treated optical signals into a micro-ring resonator (MRR) array, where the micro-ring-resonator array includes a plurality of micro-ring resonators that are connected in series.

S103: applying a corresponding electric current to the micro-ring-resonator array, to adjust a transfer function of each of the micro-ring resonators to reach a target value.

S104: feeding an optical signal outputted by the micro-ring-resonator array into a photodiode, to obtain an operation result of the average pooling of the neural network.

In some embodiments, the present application, by using the transfer functions of the micro-ring resonators as the basis of the simulated solution adapted for the average pooling in the optical neural network, by applying electric-current heating, may change the effective refractive index of the micro-ring resonators, and accordingly may adjust the transfer functions of the micro-ring resonators to the target value, and, by using the photodiode, may sum all of the optical signals outputted by the micro-ring resonators, thereby solving the problem of the average pooling in ANNs, providing an optical solution of the critical modules for fully optical artificial-intelligence calculation, and having the advantages of a high speed and a low power consumption.

It should be noted that pooling is an important operator in artificial neural networks, and pooling may reduce the size of the feature graph, and maintain a certain invariability, for example, rotation, translation and stretching. The commonly used pooling methods include max pooling and the average pooling. As shown in FIG. 2, in the average pooling, the average value of the neurons in the pooling core is calculated and used as the output.

One time of the operation in the average pooling may be expressed as:

$$y = \frac{1}{{n}^{2}} {\sum }_{i = 1}^{{n}^{2}} {x}_{i} \qquad ( 1 )$$

where n×n is the size of the pooling core, xᵢ is the neuron inputted into the pooling layer, and y is the neuron outputted by the pooling layer. When n=2, one time of the operation in the pooling layer may be expressed as:

y=(x₁+x₂+x₃+x₄)/4 (2)

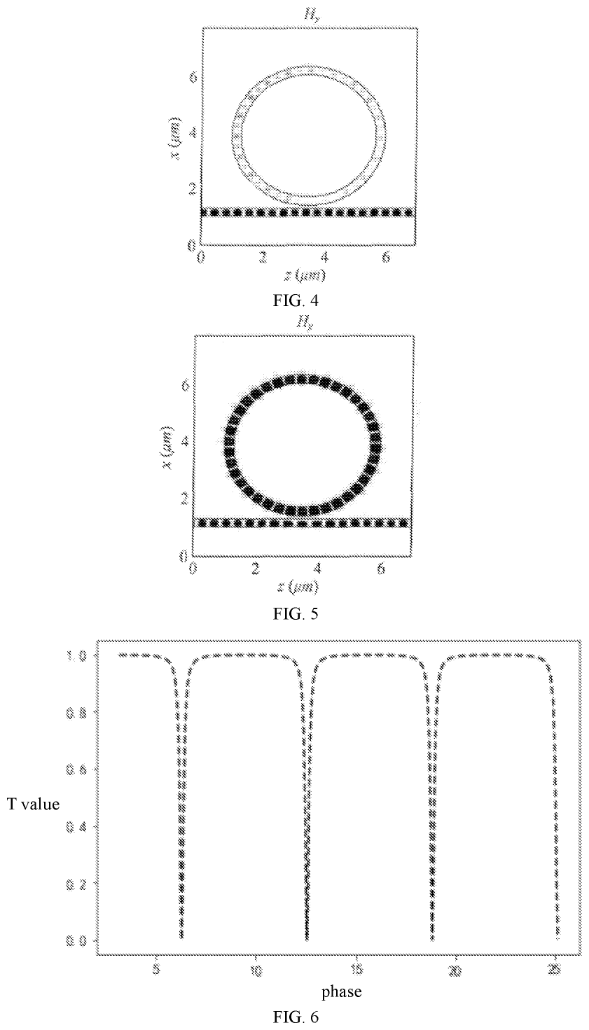

In some embodiments, as shown in FIG. 3, each of the micro-ring resonators MRR may include one straight waveguide and one micro-ring waveguide. In some embodiments, the MRRs are silicon-based MRRs of the All-pass type. FIGS. 4 and 5 show the light-intensity distribution diagrams of the All-pass-type MRRs in the disresonance and resonance situations respectively. The optical signal enters from the inputting end. When the wavelength Ai of the incident light satisfies the resonance condition, most of the optical signal with that wavelength is restrained in the micro ring, and the direct-passing end has almost no output. When the resonance condition is not satisfied, the optical signal entering the micro ring has destructive interference, and the inputted optical waves are outputted directly from the direct-passing end. Therefore, the micro rings have the most basic function of filtering.

When light is transmitted in the micro ring, it is restrained strongly by the micro ring. When it satisfies the condition that the optical path difference generated when it is transmitted around the micro ring by one round is an integral multiple of the wavelength of the optical signal, resonance happens, and the intensity of the optical signal continuously increases. The condition that enables it to have interaction and be intensified is referred to as the resonance condition. The resonance equation of the micro ring is:

2πRn_{eff}=mλᵢ (3)

where λᵢ is the wavelength, m is the integral multiple of the wavelength of the optical signal, R is the radius of the MRR, and n_{eff} is the effective refractive index of the light. The light with the wavelength satisfying the formula (3) satisfies the resonance condition, and is restrained in the micro ring. It may be known from the resonance equation (3) that the unequal wavelengths correspond to unequal micro-ring radii. In some embodiments, the micro-ring radii of the MRRs are unequal. When an electric current passes through the MRR, the MRR is heated, which results in the changing of the effective refractive index n_{eff} of the light, to cause the resonance wavelength to drift, whereby part of the light restrained in the micro ring is outputted from the direct-passing end.

The expression of the transfer function of the intensity of the light exiting from the through hole at the direct-passing end and the intensity of the light entering the input port of the all-pass resonator MRR is as follows:

$${T}_{n} ( {ϕ}_{i} ) = \frac{{a}^{2} - 2 racos ( {ϕ}_{i} ) + {r}^{2}}{1 - 2 racos ( {ϕ}_{i} ) + {( ar )}^{2}} \qquad ( 4 )$$

where ϕᵢ is the phase of the MRR, r is a self-coupling coefficient, and a defines the propagation loss of a ring-type directional coupler. The value range of the transfer function is [0,1]. When the amplitude of the inputted optical signal is Eᵢₙ (the light intensity is |Eᵢₙ|²), then the light intensity outputted from the MRR is:

|Eₒᵤₜ|²=Tₙ(ϕᵢ)|Eᵢₙ|² (5)

The expression of the phase ϕᵢ is:

$${ϕ}_{i} = \frac{4 {π}^{2} \cdot R \cdot {n}_{eff}}{{λ}_{i}} \qquad ( 6 )$$

FIG. 6 shows a diagram of the variation of the transfer function Tₙ(ϕᵢ) of the All-pass micro ring with the phase ϕᵢ.

When an electric current passes through the MRR, the MRR is heated, which results in the changing of n_{eff}, which results in the changing of the phase ϕᵢ, and finally influences the transfer function Tₙ(ϕᵢ) of the light intensity. In other words, when the amplitude of the inputted optical signal is Eᵢₙ (the light intensity is |Eᵢₙ|²), by applying electric-current heating to the silicon-based micro ring, the transfer function Tₙ(ϕᵢ) is changed, thereby obtaining the wanted outputted light intensity |Eₒᵤₜ|². The present application realizes the average-pooling operation of the neural network based on the above-described property of the All-pass micro rings by using the MRR array.

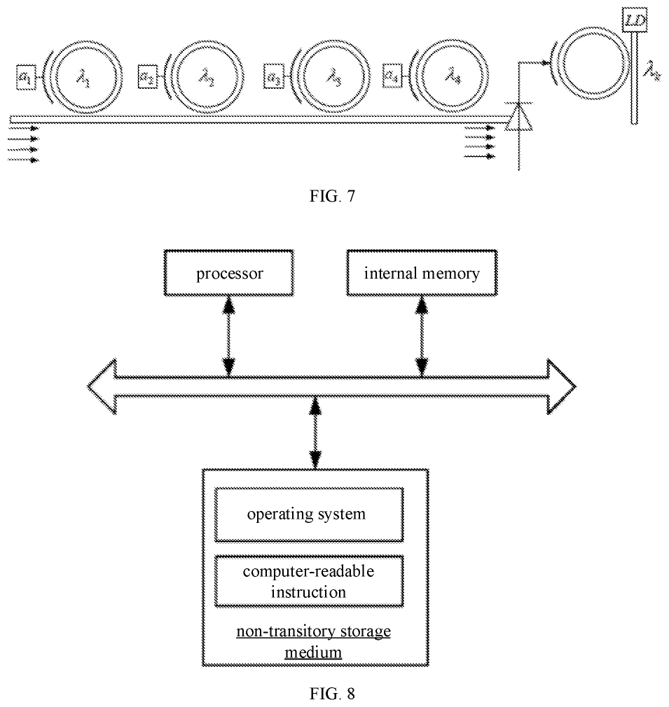

In some embodiments, the quantity of the types of the wavelengths of the to-be-treated optical signals is equal to the quantity of the MRRs; and the wavelengths of the to-be-treated optical signals correspond to the radii of the MRRs one to one. As shown in FIG. 7, the to-be-treated optical signals have four wavelengths, i.e., λ₁, λ₂, λ₃ and λ₄. In this case, four MRRs are provided, where the first MRR corresponds to the to-be-treated signal with the wavelength λ₁, the second MRR corresponds to the to-be-treated signal with the wavelength λ₂, the third MRR corresponds to the to-be-treated signal with the wavelength λ₃, and the fourth MRR corresponds to the to-be-treated signal with the wavelength λ₄.

In some embodiments, before the operation of applying the corresponding electric current to the micro-ring resonator MRR array, the method further includes: by the to-be-treated optical signals with the unequal wavelengths, performing resonance with the corresponding MRRs. As shown in FIG. 7, the to-be-treated signal corresponding to the wavelength λ₁ performs resonance with the first MRR, the to-be-treated signal corresponding to the wavelength λ₂ performs resonance with the second MRR, the to-be-treated signal corresponding to the wavelength λ₃ performs resonance with the third MRR, and the to-be-treated signal corresponding to the wavelength λ₄ performs resonance with the fourth MRR.

In an embodiment, as shown in FIG. 7, because the plurality of micro-ring resonators are connected in series, the straight waveguides of all of the micro-ring resonators MRR of the micro-ring resonator MRR array may be the same shared straight waveguide. The shared straight waveguide is provided with an input port and a direct-passing (output) port. In this case, the photodiode is located at the direct-passing port.

In some embodiments, the to-be-treated optical signals with the unequal wavelengths have unequal light intensities. In other words, the light intensities of the wavelengths of λ₁, λ₂, λ₃ and λ₄ are |E₁|², |E₂|², |E₃|² and |E₄|² respectively.

As shown in FIG. 7, the four inputted light intensities |E₁|², |E₂|², |E₃|² and |E₄|² are inputted at the input port with the wavelengths of λ₁, λ₂, λ₃ and λ₄ respectively, and perform resonance with the four MRRs. Subsequently, by regulating the phases ϕᵢ of the four MRRs, the transfer function is

$${T}_{n} ( {ϕ}_{i} ) = \frac{1}{4} ,$$

and accordingly the light intensities outputted at the output port of the MRR array are

$$\frac{1}{4} {\vert {E}_{1} \vert}^{2} , \frac{1}{4} {\vert {E}_{2} \vert}^{2} , \frac{1}{4} {\vert {E}_{3} \vert}^{2} and \frac{1}{4} {\vert {E}_{4} \vert}^{2} .$$

Subsequently, by using the photodiode, all of the optical signals are summed. Accordingly, the 2×2 average pooling of the neural network is realized.

In some embodiments, a computer device is provided, and the computer device may be a mobile smart platform or robot, and its internal structural diagram may be as shown in FIG. 8. The computer device includes a processor and a memory that are connected by a system bus. The processor of the computer device is configured to provide the capacity of calculation and controlling. The memory of the computer device includes a non-transitory storage medium and an internal memory. The non-transitory storage medium stores an operating system and a computer-readable instruction. The internal memory provides the environment for the running of the operating system and the computer-readable instruction in the non-transitory storage medium. The computer-readable instruction, when executed by the processor, implements the operation for performing average pooling of a neural network.

A person skilled in the art may understand that the structure shown in FIG. 8 is a block diagram of part of the structures relevant to the solutions of the present application, and does not form a limitation on the computer device to which the solutions of the present application are applied, and the computer device may include components more or less than those shown in the figure or a combination of some of the components, or has a different arrangement of the components.

Correspondingly, an embodiment of the present application further discloses a computer device, where the computer device includes a memory and one or more processors, and the memory stores a computer-readable instruction, and the computer-readable instruction, when executed by the one or more processors, causes the one or more processors to implement the method for performing average pooling of a neural network according to any one of the above embodiments.

An embodiment of the present application further discloses one or more non-transitory computer-readable storage mediums storing a computer-readable instruction, where the computer-readable instruction, when executed by one or more processors, causes the one or more processors to implement the method for performing average pooling of a neural network according to any one of the above embodiments.

The process of the above-described method may refer to the corresponding contents disclosed in the above embodiments, which is not discussed further herein.

The embodiments of the description are described in the mode of progression, each of the embodiments emphatically describes the differences from the other embodiments, and the same or similar parts of the embodiments may refer to each other. Regarding the device and the storage medium according to the embodiments, because they correspond to the methods according to the embodiments, they are described simply, and the relevant parts may refer to the description on the methods.

A person skilled in the art may further understand that the units and the algorithm steps of the examples described with reference to the embodiments disclosed herein may be implemented by using electronic hardware, computer software or a combination thereof. In order to clearly explain the interchangeability between the hardware and the software, the above description has described generally the configurations and the steps of the examples according to the functions. Whether those functions are executed by hardware or software depends on the applications and the design constraints of the technical solutions. A person skilled in the art may employ different methods to implement the described functions with respect to each of the applications, but the implementations should not be considered as extending beyond the scope of the present application.

The steps of the method or algorithm described with reference to the embodiments disclosed herein may be implemented directly by using hardware, a software module executed by a processor or a combination thereof. The software module may be embedded in a Random Access Memory (RAM), an internal memory, a read-only memory (ROM), an electrically programmable ROM, an electrically erasable programmable ROM, a register, a hard disk, a removable disk, a CD-ROM, or a storage medium in any other form well known in the art.

In conclusion, the method for performing average pooling of a neural network according to the embodiments of the present application includes: acquiring a plurality of to-be-treated optical signals with unequal wavelengths; inputting the to-be-treated optical signals into a micro-ring-resonator array, where the micro-ring-resonator array includes a plurality of micro-ring resonators that are connected in series; applying a corresponding electric current to the micro-ring-resonator array, to adjust a transfer function of each of the micro-ring resonators to reach a target value; and feeding an optical signal outputted by the micro-ring-resonator array into a photodiode, to obtain an operation result of the average pooling of the neural network. The present application, by using the transfer functions of the micro-ring resonators as the basis of the simulated solution adapted for the average pooling in the optical neural network, by applying electric-current heating, may adjust the transfer functions of the micro-ring resonators to the target value, and, by using the photodiode, may sum all of the optical signals outputted by the micro-ring resonators, thereby solving the problem of the average pooling in ANNs, providing an optical solution of the critical modules for fully optical artificial-intelligence calculation, and having the advantages of a high speed and a low power consumption. Furthermore, the present application further provides the computer device and the non-transitory computer-readable storage medium corresponding to the method for performing average pooling of a neural network, which further enables the method to have more practical applicability, and the computer device and the non-transitory computer-readable storage medium have the corresponding advantages.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device including the element.

The method for performing average pooling of a neural network, the device and the storage medium according to the present application have been described in detail above. The principle and the embodiments of the present application are described herein with reference to the examples, and the description of the above embodiments is merely intended to facilitate to comprehend the method according to the present application and its core concept. Moreover, for a person skilled in the art, according to the concept of the present application, the embodiments and the range of application may be varied. In conclusion, the contents of the description should not be understood as limiting the present application.

1. A method for performing average pooling of a neural network, wherein the method comprises:
acquiring a plurality of to-be-treated optical signals with unequal wavelengths;
inputting the to-be-treated optical signals into a micro-ring-resonator array, wherein the micro-ring-resonator array comprises a plurality of micro-ring resonators that are connected in series;
applying a corresponding electric current to the micro-ring-resonator array, to adjust a transfer function of each of the micro-ring resonators to reach a target value; and
feeding an optical signal outputted by the micro-ring-resonator array into a photodiode, to obtain an operation result of the average pooling of the neural network.

2. The method according to claim 1, wherein each of the micro-ring resonators comprises one straight waveguide and one micro-ring waveguide; and
micro-ring radii of the micro-ring resonators are unequal.

3. The method according to claim 1, wherein a quantity of types of the wavelengths of the to-be-treated optical signals is equal to a quantity of the micro-ring resonators; and
the wavelengths of the to-be-treated optical signals correspond to radii of the micro-ring resonators one to one.

4. The method according to claim 1, wherein before the operation of applying the corresponding electric current to the micro-ring-resonator array, the method further comprises:
by the to-be-treated optical signals with the unequal wavelengths, performing resonance with the corresponding micro-ring resonators.

5. The method according to claim 1, wherein straight waveguides of all of the micro-ring resonators of the micro-ring-resonator array are a same shared straight waveguide;
the shared straight waveguide is provided with an input port and a direct-passing port; and
the photodiode is located at the direct-passing port.

6. The method according to claim 1, wherein light intensities of the to-be-treated optical signals with the unequal wavelengths are unequal.

7. The method according to claim 1, wherein the method further comprises:
when the to-be-treated optical signals with four wavelengths are inputted into the micro-ring-resonator array, determining the target value to be ¼; and
when the target value is ¼, obtaining the operation result of 2×2 average pooling of the neural network.

8. A computer device, wherein the computer device comprises a memory and one or more processors, and the memory stores a computer-readable instruction, and the computer-readable instruction, when executed by the one or more processors, causes the one or more processors to implement operations comprising:
acquiring a plurality of to-be-treated optical signals with unequal wavelengths;
inputting the to-be-treated optical signals into a micro-ring-resonator array, wherein the micro-ring-resonator array comprises a plurality of micro-ring resonators that are connected in series;
applying a corresponding electric current to the micro-ring-resonator array, to adjust a transfer function of each of the micro-ring resonators to reach a target value; and
feeding an optical signal outputted by the micro-ring-resonator array into a photodiode, to obtain an operation result of average pooling of a neural network.

9. A non-transitory computer-readable storage medium,
storing a computer-readable instruction, wherein the computer-readable instruction, when executed by one or more processors, causes the one or more processors to implement operations comprising:
acquiring a plurality of to-be-treated optical signals with unequal wavelengths;
inputting the to-be-treated optical signals into a micro-ring-resonator array, wherein the micro-ring-resonator array comprises a plurality of micro-ring resonators that are connected in series;
applying a corresponding electric current to the micro-ring-resonator array, to adjust a transfer function of each of the micro-ring resonators to reach a target value; and
feeding an optical signal outputted by the micro-ring-resonator array into a photodiode, to obtain an operation result of average pooling of a neural network.

10. The method according to claim 1, wherein in the average pooling, an average value of neurons in a pooling core is calculated and used as an output.

11. The method according to claim 10, wherein one time of operation in the average pooling is expressed as:
$$y = \frac{1}{{n}^{2}} {\sum }_{i = 1}^{{n}^{2}} {x}_{i} ;$$
where n×n is a size of the pooling core, xᵢ is a neuron inputted into a pooling layer, and y is a neuron outputted by the pooling layer.

12. The method according to claim 11, wherein when n=2, one time of operation in the pooling layer is expressed as:
y=(x₁+x₂+x₃+x₄)/4.

13. The method according to claim 2, wherein the micro-ring resonators are silicon-based micro-ring resonators of an All-pass type.

14. The method according to claim 13, wherein the transfer function of an intensity of light exiting from a through hole at a direct-passing end and an intensity of light entering a input port of the all-pass micro-ring resonator is expressed as:
$${T}_{n} ( {ϕ}_{i} ) = \frac{{a}^{2} - 2 racos ( {ϕ}_{i} ) + {r}^{2}}{1 - 2 racos ( {ϕ}_{i} ) + {( ar )}^{2}} ;$$
where ϕᵢ is a phase of the micro-ring resonator, r is a self-coupling coefficient, and a defines a propagation loss of a ring-type directional coupler.

15. The method according to claim 14, wherein a value range of the transfer function is [0,1].

16. The method according to claim 14, wherein when an amplitude of an inputted optical signal is Eᵢₙ and a light intensity of the inputted optical signal is |Eᵢₙ|², a light intensity outputted from the micro-ring resonator is:

|Eₒᵤₜ|²=Tₙ(ϕ)|Eᵢₙ|²; and
the phase ϕᵢ is expressed as:
$${ϕ}_{i} = \frac{4 {π}^{2} \cdot R \cdot {n}_{eff}}{{λ}_{i}} ;$$
where λᵢ is a wavelength, R is the radius of the micro-ring resonator, and n_{eff} is an effective refractive index of light.

17. The computer device according to claim 8, wherein each of the micro-ring resonators comprises one straight waveguide and one micro-ring waveguide; and
micro-ring radii of the micro-ring resonators are unequal.

18. The computer device according to claim 8, wherein a quantity of types of the wavelengths of the to-be-treated optical signals is equal to a quantity of the micro-ring resonators; and
the wavelengths of the to-be-treated optical signals correspond to radii of the micro-ring resonators one to one.

19. The non-transitory computer-readable storage medium according to claim 9, wherein each of the micro-ring resonators comprises one straight waveguide and one micro-ring waveguide; and
micro-ring radii of the micro-ring resonators are unequal.

20. The non-transitory computer-readable storage medium according to claim 9, wherein a quantity of types of the wavelengths of the to-be-treated optical signals is equal to a quantity of the micro-ring resonators; and
the wavelengths of the to-be-treated optical signals correspond to radii of the micro-ring resonators one to one.
